(19) United States
(12) Patent Application Publication
(10) Pub. No.: US 2005/0127457 A1
(43) Pub. Date: Jun. 16, 2005

(54) Signal charge converter for charge transfer element

(76) Inventors: Jae-Seob Roh, Anyang-City (KR); Jung-Hyun Nam, Suwon-City (KR); Jeong-Ho Lyu, Suwon-City (KR); Duck-Hyung Lee, Yongin-City (KR); Hae-Kyung Kong, Yongin-City (KR); Yi-Tae Kim, Suwon-City (KR)

Correspondence Address: LAW OFFICE OF MONICA H CHOI, P O BOX 3424, DUBLIN, OH, 430160204, US

(21) Appl. No.: 10/874,042

(22) Filed: Jun. 22, 2004

(30) Foreign Application Priority Data
Dec. 16, 2003 (KR) P2003-0091868

(51) Int. Cl. H01L 29/76

(52) U.S. Cl. 257/392

(57) ABSTRACT

A signal converter, for converting signal charge into a voltage, comprises a first driver FET for a first stage that receives the signal charge. A subsequent driver FET is coupled to an output of the first driver FET, and a gate dielectric thickness of the subsequent driver FET is decreased. The subsequent driver FET is either for a second stage or for a third stage. The decrease of the gate dielectric thickness for the subsequent driver FET increases the voltage gain AVₜₒₜₐₗ without decreasing the charge transfer efficiency such that the overall sensitivity of the signal converter is enhanced.

### CROSS-REFERENCE TO RELATED APPLICATION(S)

The present application claims priority under 35 U.S.C. § 119 to Korean Patent Application No. P2003-0091868, filed on Dec. 16, 2003, which is incorporated herein by reference in its entirety.

### TECHNICAL FIELD

The present invention relates generally to charge transfer elements such as CCD's (charge coupled devices) in imaging systems, and more particularly, to a signal charge converter that converts signal charge from a charge transfer element to a voltage with enhanced sensitivity.

### BACKGROUND OF THE INVENTION

FIG. 1 shows an example imaging system 100 including an array of photo-diodes such as an example photo-diode 102. Each photo-diode accumulates signal charge that indicates an intensity of illumination at the pixel location of the photo-diode. A vertical BCCD (buried charge coupled device) is disposed along each column of photo-diodes, including a first vertical BCCD 104 for the first column, a second vertical BCCD 106 for the second column, and so on up to a last vertical BCCD 108 for the last column.

Each vertical BCCD shifts signal charge from the column of photo-diodes to a horizontal BCCD 110. The horizontal BCCD 110 shifts signal charge from the vertical BCCDs to an output circuit 112 (shown outlined in dashed lines in FIG. 1). The output circuit 112 converts signal charge from the horizontal BCCD 110 into a voltage, Vₒᵤₜ.

Within the output circuit 112, an output MOSFET (metal oxide semiconductor field effect transistor) 114 is coupled between the horizontal BCCD 110 and a charge accumulation region 116. In addition, a reset MOSFET 118 is coupled between a reset voltage, Vᵣₑₛₑₜ, source and the charge accumulation region 116. The charge accumulation region 116 is typically a highly doped junction that accumulates signal charge from the horizontal BCCD 110. The output MOSFET 114 is biased to transfer signal charge from the last stage of the horizontal BCCD 110 to a charge node 120 of the charge accumulation region 116.

The reset MOSFET 118 is turned on for resetting the charge node 120 of the charge accumulation region 116 to the reset voltage, Vᵣₑₛₑₜ. A RESET control signal is applied on the gate of the reset MOSFET 118. Typically, the reset MOSFET 118 remains turned off when signal charges from the horizontal BCCD 110 are being accumulated by the charge accumulation region 116.

A signal converter 122 is coupled to the charge accumulation region 116 for converting signal charge accumulated at the region 116 to a corresponding voltage, Vₒᵤₜ. The level of such a voltage, Vₒᵤₜ, indicates the amount of signal charge accumulated at the region 116, and thus the intensity of illumination corresponding to such a signal charge.

FIG. 2 shows an example implementation of the signal converter 122 (outlined in dashed lines) according to the prior art. Elements having the same reference number in FIGS. 1, 2, 3, 4, and 5 refer to elements having similar structure and function. The signal converter 122 of FIG. 2 includes a first driver MOSFET 132 and a first load MOSFET 134 comprising a first source follower stage 133. In addition, a second driver MOSFET 136 and a second load MOSFET 138 comprise a second source follower stage 139. Furthermore, a third driver MOSFET 140 and a third load MOSFET 142 comprise a third source follower stage 143.

Within each source follower stage, the source of the respective driver MOSFET is coupled to the drain of the respective load MOSFET. The drains of the driver MOSFETs 132, 136, and 140 are coupled to a high bias voltage VDD, and the sources of the load MOSFETs 134, 138, and 142 are coupled to a low bias voltage GND. The gates of the load MOSFETs 134, 138, and 142 are coupled to a gate biasing voltage, which is GND in the example of FIG. 2.

The gate of the first driver MOSFET 132 is coupled to the charge accumulation region 116. The gate of each subsequent driver MOSFET is coupled to the source of the prior driver MOSFET. Thus, the gate of the second driver MOSFET 136 is coupled to the source of the first driver MOSFET 132, and the gate of the third driver MOSFET 140 is coupled to the source of the second driver MOSFET 136. The gate of each driver MOSFET is the input, and the source of each driver MOSFET is the output, for each corresponding source follower stage in FIG. 2. The source of the third driver MOSFET 140 provides the output voltage, Vₒᵤₜ, of the signal converter 122.

Further referring to FIG. 2, the first driver MOSFET 132 is implemented as an enhancement-mode MOSFET, whereas the other MOSFETs 134, 136, 138, 140, and 142 are each implemented as a depletion-mode MOSFET. Generally, an enhancement-mode MOSFET has no conduction when V_{GS}=0V, whereas, a depletion-mode MOSFET has a conducting channel implanted between the source and drain for conduction when V_{GS}=0V.

The sensitivity of the signal converter 122, S_{V}, is a characteristic that indicates the quality of the signal converter 122. The sensitivity of the signal converter 122, S_{V}, is expressed as follows:
S_{V}=CE×AVₜₒₜₐₗ

CE is the charge transfer efficiency, and AVₜₒₜₐₗ is the total voltage gain through the three source follower stages 133, 139, and 143 of the signal converter 122. Thus, AVₜₒₜₐₗ is expressed as follows:
AVₜₒₜₐₗ=AV₁ₛₜ×AV_{2nd}×AV_{3rd}
AV₁ₛₜ is the voltage gain of the first source follower stage 133, AV_{2nd} is the voltage gain of the second source follower stage 139, and AV_{3rd} is the voltage gain of the third source follower stage 143.

The voltage gain AV for any source follower stage is expressed as follows:
AV=gₘ/(gₘ+g_{ds}+g_{mb})
gₘ is the transconductance, g_{ds} is the conductance through the channel, and g_{mb} is the back-gate transconductance, for the driver MOSFET of the source follower stage. The transconductance gₘ for a driver MOSFET is generally expressed as follows:
gₘ=[2μₒₓCₒₓ(W/L)I_{D}]^{1/2}
μₒₓ is the charge mobility, Cₒₓ is the gate capacitance, W is the gate width, L is the gate length, and I_{D} is the drain current, for the driver MOSFET.

In addition, the charge transfer efficiency, CE, is expressed as follows:
CE=q/C_{S}=q/[C_{FD}+C_{GS}+C_{GD}+C_{G}]
q is the electron charge, and referring to FIGS. 1 and 2, C_{S} is the total capacitance at the storage node 120 of the charge accumulation region 116. FIG. 3 shows an example layout of the output MOSFET 114, the charge accumulation region 116, the reset MOSFET 118, and the first driver MOSFET 132. Such components are coupled to the storage node 120 of the charge accumulation region 116.

The output MOSFET 114 is comprised of a gate 152 disposed between a drain 154 and a source 156. The reset MOSFET 118 is comprised of a gate 158 disposed between a drain 160 and a source 154. In addition, the first driver MOSFET 132 is comprised of a gate 162 disposed between a drain 164 and a source 166. Thus, the total capacitance at the storage node 120, C_{S}, is comprised of:
C_{FD} which is the capacitance of the floating diffusion junction 116;
C_{GS} which is the overlap capacitance between the gate 158 and the source 154 of the reset MOSFET 118 (i.e., within an overlap area 172 outlined in dashed lines in FIG. 3);
C_{GD} which is the overlap capacitance between the gate 152 and the drain 154 of the output MOSFET 114 (i.e., within an overlap area 174 outlined in dashed lines in FIG. 3); and
C_{G} which is the gate capacitance of the first driver MOSFET 132.

FIG. 4 shows an alternative implementation 122A of the signal converter as disclosed in U.S. Pat. No. 5,432,364 to Ohki et al. Such a signal converter 122A uses the three driver MOSFETs 132, 136, and 140 with the corresponding three load MOSFETs 134, 138, and 142 for the three source follower stages. In addition, the drain of the first driver MOSFET 132 is coupled to VDD via a resistor 182, and the source of the second load MOSFET 138 is coupled to GND via a resistor 184. The sources of the first and third load MOSFETs 134 and 142 are coupled together to GND via a capacitor 186. A gate bias voltage source 188 and a gate bias capacitor 190 are coupled to the gates of the load MOSFETs 134, 138, and 142.

The signal converter 122A of FIG. 4 operates similarly to the signal converter 122 of FIG. 2. However, referring to FIGS. 4 and 5, a gate dielectric 192 for the first driver MOSFET 132 is thinner than a gate dielectric 194 for the second driver MOSFET 136. FIG. 5 shows a cross-sectional view of the first and second driver MOSFETs 132 and 136, as disclosed in U.S. Pat. No. 5,432,364.

Referring to FIG. 5, the first and second driver MOSFETs 132 and 136 are formed in a P-well 196. The first driver MOSFET 132 is comprised of a gate 132A, a drain 132B, and a source 132C, and the second driver MOSFET 136 is comprised of a gate 136A, a drain 136B, and a source 136C. An interconnect structure 198 couples the source 132C of the first driver MOSFET 132 to the gate 136A of the second driver MOSFET 136.

Referring to FIGS. 4 and 5, the thickness of the gate dielectric 192 for the first driver MOSFET 132 is decreased from that of other MOSFETs, such as that of the second driver MOSFET 136, within the signal converter 122A to reduce 1/f noise. In addition in that case, the voltage gain AV₁ₛₜ of the first source follower stage in increased since the transconductance gₘ of the first driver MOSFET 132 is increased.

However, the charge transfer efficiency disadvantageously decreases since decreased thickness of the gate dielectric 192 increases the gate capacitance C_{G} of the first driver MOSFET 132. As a result, the overall sensitivity of the signal converter 122A of the prior art may not necessarily be enhanced and may even be deteriorated by decreasing the thickness of the gate dielectric 192 of just the first driver MOSFET 132.

Nevertheless, increasing overall sensitivity for a signal converter results in higher quality of the imaging system. Thus, a signal converter is desired with increased overall sensitivity to enhance the quality of the imaging system.

### SUMMARY OF THE INVENTION

Accordingly, in a general aspect of the present invention, a gate dielectric thickness of at least one subsequent driver FET after a first driver FET is decreased to enhance the overall sensitivity of a signal converter.

In an embodiment of the present invention, a signal converter for converting signal charge into a voltage comprises a first driver FET that receives the signal charge. In addition, a subsequent driver FET is coupled to an output of the first driver FET, and a gate dielectric thickness of the subsequent driver FET is less than a gate dielectric thickness of at least one other FET of the signal converter. The driver FETs are each configured as a source follower in an example embodiment of the present invention.

In one embodiment of the present invention, the first driver FET is for a first stage, and the subsequent driver FET is for a second stage after the first stage. In that case, the gate dielectric thickness of the subsequent driver FET is less than a gate dielectric thickness of the first driver FET, or is substantially equal to the gate dielectric thickness of the first driver FET. Alternatively, the gate dielectric thickness of the first driver FET is decreased even further to be less than the gate dielectric thickness of the subsequent driver FET.

In another embodiment of the present invention, the first driver FET is for a first stage, and the subsequent driver FET is for a third stage coupled to the first stage via a second stage having a second driver FET. In that case, the gate dielectric thickness of the subsequent driver FET is less than a gate dielectric thickness of the first driver FET, or is substantially equal to the gate dielectric thickness of the first driver FET. Alternatively, the gate dielectric thickness of the first driver FET is decreased even further to be less than the gate dielectric thickness of the subsequent driver FET. In another embodiment of the present invention, the gate dielectric thickness of the subsequent driver FET is less than a same gate dielectric thickness for the first and second driver FETs.

In yet another embodiment of the present invention, a last driver FET is coupled to an output of the subsequent driver FET to generate an output voltage. In that case, the gate dielectric thickness of the subsequent driver FET is less than a gate dielectric thickness of the last driver FET, or is substantially equal to the gate dielectric thickness of the last driver FET. Alternatively, the gate dielectric thickness of the last driver FET is decreased even further to be less than the gate dielectric thickness of the subsequent driver FET. In another embodiment of the present invention, the gate dielectric thickness of the subsequent driver FET is less than a same gate dielectric thickness for the first and last driver FETs.

In a further embodiment of the present invention, each of the driver FETs is coupled to a respective load FET. In that case, in one example embodiment of the present invention, each of the driver FETs has a same gate dielectric thickness that is less than a gate dielectric thickness of at least one of the load FETs.

In another example embodiment of the present invention, the gate dielectric thickness of the subsequent driver FET is less than a gate dielectric thickness of at least one of the load FETs, or is less than each respective gate dielectric thickness for all of the load FETs.

The signal converter of such embodiments of the present invention may advantageously be used to generate a voltage from signal charge that is output from a CCD (charge coupled device) of a photo-diode imaging system.

In this manner, the gate dielectric thickness is decreased for at least one subsequent driver FET after the first stage driver FET. Such decrease of the gate dielectric thickness for at least one subsequent driver FET increases the total voltage gain AVₜₒₜₐₗ without decreasing the charge transfer efficiency of the signal converter. Thus, the overall sensitivity of the signal converter is enhanced.

These and other features and advantages of the present invention will be better understood by considering the following detailed description of the invention which is presented with the attached drawings.

### BRIEF DESCRIPTION OF THE DRAWINGS

FIG. 1 shows a block diagram of a photo-diode imaging system, according to the prior art;

FIG. 2 shows a circuit diagram of an example implementation of a signal converter within an output circuit of FIG. 1, according to the prior art;

FIG. 3 shows a layout of components of the output circuit of FIG. 1, according to the prior art;

FIG. 4 shows a circuit diagram of another example implementation of a signal converter, as disclosed in the prior art;

FIG. 5 shows a cross-sectional view of first and second driver MOSFETs within the signal converter of FIG. 4, according to the prior art;

FIG. 6 shows a circuit diagram of a signal converter with enhanced sensitivity, according to an embodiment of the present invention;

FIGS. 7, 8, 9, 10, 11, 12, 13, 14, and 15 show cross-sectional views of MOSFETs within the signal converter of FIG. 6, with various possibilities of gate dielectric thicknesses of such MOSFETs, according to an embodiment of the present invention;

FIG. 16 shows an alternative cross-sectional view of the MOSFETs within the signal converter of FIG. 6, with a first driver MOSFET formed within an isolated P-well, according to another embodiment of the present invention;

FIG. 17 shows an alternative cross-sectional view of the MOSFETs within the signal converter of FIG. 6, with a source of a driver MOSFET and a drain of a load MOSFET of each staged merged together, according to another embodiment of the present invention;

FIG. 18 shows an alternative circuit diagram of a signal converter with enhanced sensitivity, according to another embodiment of the present invention; and

FIG. 19 shows an imaging system using the signal converter of FIG. 6, according to another embodiment of the present invention.

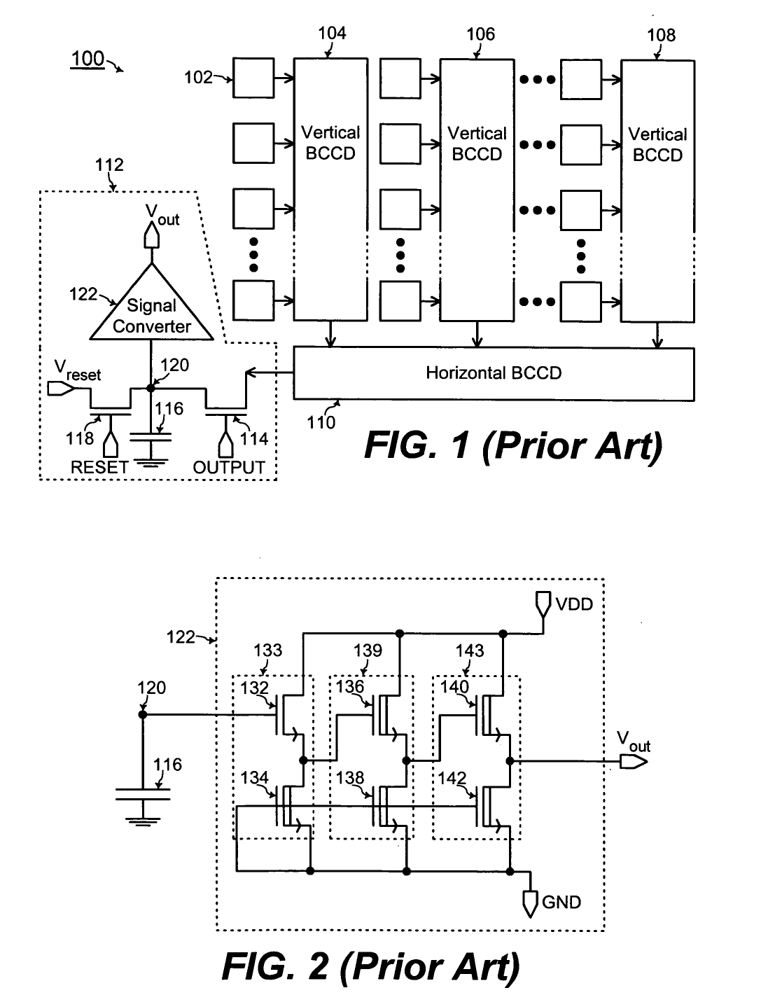

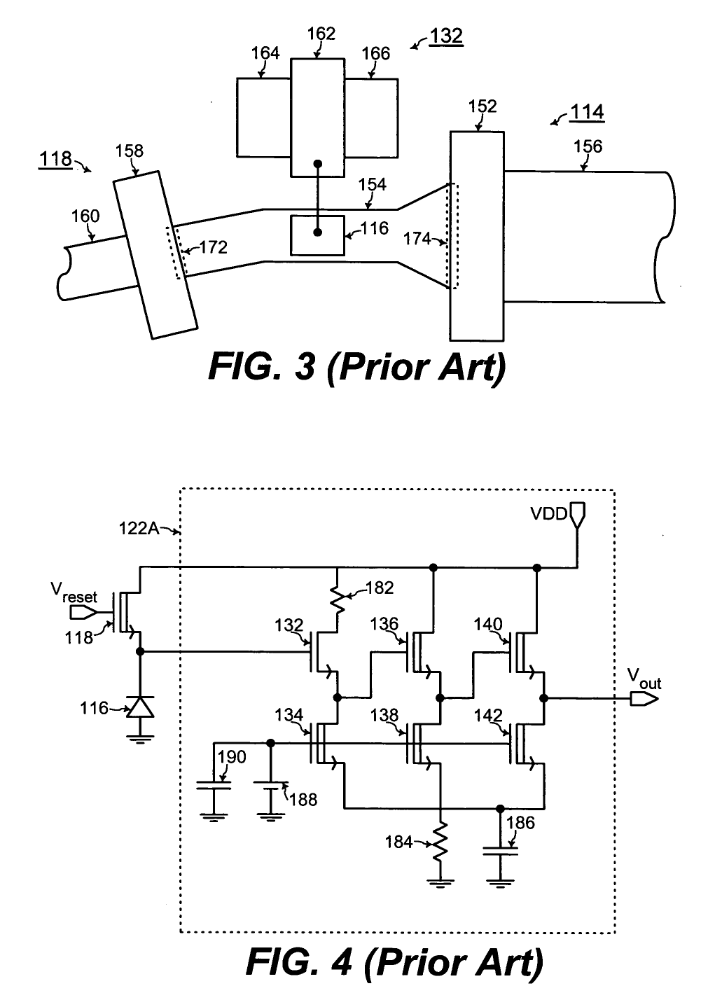

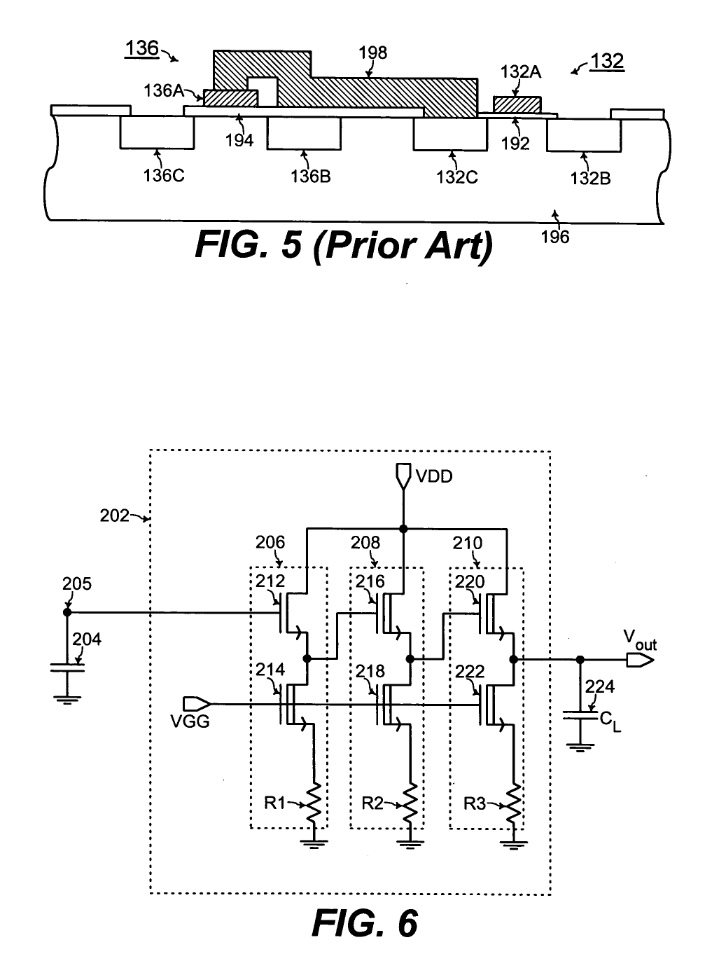

The figures referred to herein are drawn for clarity of illustration and are not necessarily drawn to scale. Elements having the same reference number in FIGS. 1-19 refer to elements having similar structure and function.

### DETAILED DESCRIPTION

Referring to FIG. 6, a signal converter 202 converts signal charge accumulated at a charge accumulation region 204 into a voltage, Vₒᵤₜ, with enhanced sensitivity according to an embodiment of the present invention. The charge accumulation region 204 of FIG. 6 is typically formed as a highly doped junction, similar to the charge accumulation region 116 of FIGS. 1, 2, 3 and 4, in one embodiment of the present invention. Alternatively, the present invention may be practiced with any other type of charge accumulation region.

The signal converter 202 includes a first source follower stage 206, a second source follower stage 208, and a third source follower stage 210, in one embodiment of the present invention. The first source follower stage 206 includes a first driver MOSFET (metal oxide semiconductor field effect transistor) 212 and a first load MOSFET 214. The second source follower stage 208 includes a second driver MOSFET 216 and a second load MOSFET 218. The third source follower stage 210 includes a third driver MOSFET 220 and a third load MOSFET 222.

The first driver MOSFET 212 has a drain coupled to a high bias voltage VDD, a source coupled to the drain of the first load MOSFET 214, and a gate coupled to the charge accumulation region 204. In addition, the first load MOSFET 214 has a gate coupled to a gate bias voltage VGG and a source coupled to ground via a first load resistor R1.

Similarly, the second driver MOSFET 216 has a drain coupled to the high bias voltage VDD and a source coupled to the drain of the second load MOSFET 218. In addition, a gate of the second driver MOSFET 216 is coupled to the output of the first source follower stage 206 (i.e., the source of the first driver MOSFET 212). Furthermore, the second load MOSFET 218 has a gate coupled to the gate bias voltage VGG and a source coupled to ground via a second load resistor R2.

Additionally, the third driver MOSFET 220 has a drain coupled to the high bias voltage VDD and a source coupled to the drain of the third load MOSFET 222. In addition, a gate of the third driver MOSFET 220 is coupled to the output of the second source follower stage 208 (i.e., the source of the second driver MOSFET 216). Furthermore, the third load MOSFET 222 has a gate coupled to the gate bias voltage VGG and a source coupled to ground via a third load resistor R3. The output of the third source follower stage 210 provides the output voltage, Vₒᵤₜ.

Generally, the three source follower stages 206, 208, and 210 are used because the third driver MOSFET 220 of the last stage 210 is sized to drive a load capacitor 224 with sufficient speed. For example, a typical load capacitance CL is approximately 10 pF (pico-Farad), and the width of the third driver MOSFET 220 is about 1,000 μm for driving such a load capacitance with sufficient speed.

On the other hand, the size and thus the gate capacitance of the first driver MOSFET 212 of the foremost stage 206 is desired to be minimized to maximize the charge transfer efficiency of the signal converter 202. The second driver MOSFET 216 smoothly transitions between the first driver MOSFET 212 and the third driver MOSFET 220 by providing current amplification from the first driver MOSFET 212 to the third driver MOSFET 220.

Further referring to FIG. 6, the first driver MOSFET 212 is implemented as an enhancement-mode MOSFET, whereas the other MOSFETs 214, 216, 218, 220, and 222 are each implemented as a depletion-mode MOSFET. Generally, an enhancement-mode MOSFET has no conduction when V_{GS}=0V, whereas, a depletion-mode MOSFET has a conducting channel implanted between the source and drain for conduction when V_{GS}=0V.

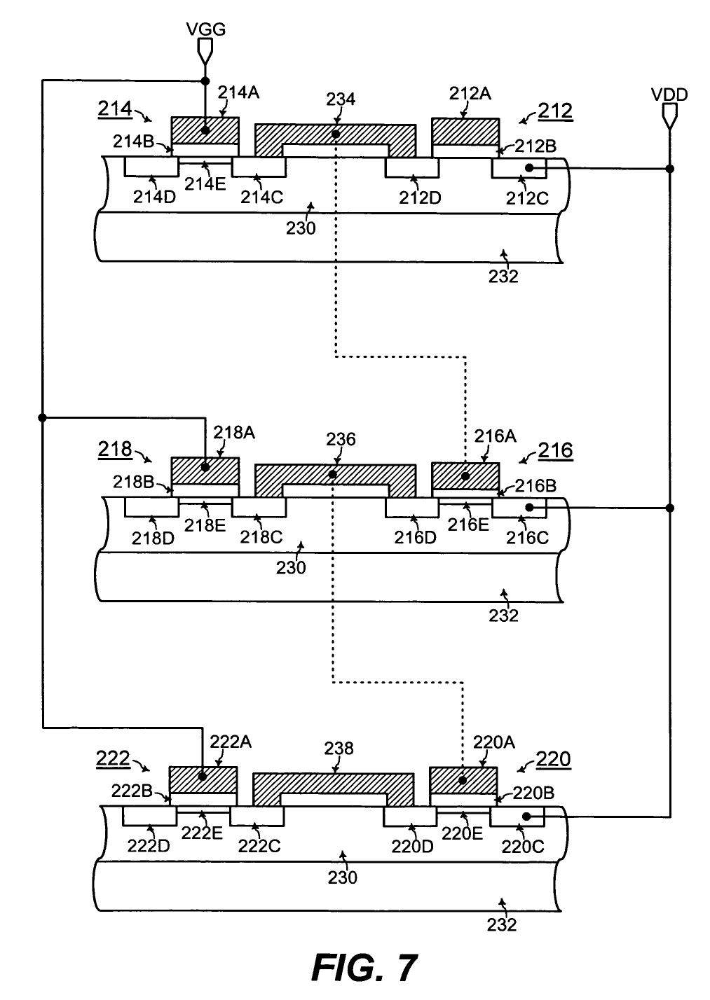

FIG. 7 shows a cross-sectional view of the MOSFETs 212, 214, 216, 218, 220, and 222 of the signal converter 202 of FIG. 6, in an example embodiment of the present invention. The MOSFETs 212, 214, 216, 218, 220, and 222 are N-channel MOSFETs formed within a P-well 230 of a semiconductor substrate 232 which is a silicon wafer for example.

Further referring to FIG. 7, the first driver MOSFET 212 includes a gate 212A, a gate dielectric 212B, a drain 212C, and a source 212D. The first load MOSFET 214 includes a gate 214A, a gate dielectric 214B, a drain 214C, a source 214D, and an implanted conducting channel 214E as a depletion-mode MOSFET. An interconnect structure 234 couples the source 212D of the first driver MOSFET 212 to the drain 214C of the first load MOSFET 214.

Similarly, the second driver MOSFET 216 includes a gate 216A, a gate dielectric 216B, a drain 216C, a source 216D, and an implanted conducting channel 216E as a depletion-mode MOSFET. The second load MOSFET 218 includes a gate 218A, a gate dielectric 218B, a drain 218C, a source 218D, and an implanted conducting channel 218E as a depletion-mode MOSFET. An interconnect structure 236 couples the source 216D of the second driver MOSFET 216 to the drain 218C of the second load MOSFET 218.

Additionally, the third driver MOSFET 220 includes a gate 220A, a gate dielectric 220B, a drain 220C, a source 220D, and an implanted conducting channel 220E as a depletion-mode MOSFET. The third load MOSFET 222 includes a gate 222A, a gate dielectric 222B, a drain 222C, a source 222D, and an implanted conducting channel 222E as a depletion-mode MOSFET. An interconnect structure 238 couples the source 220D of the third driver MOSFET 220 to the drain 222C of the third load MOSFET 222.

Further referring to FIG. 7, the thickness of the gate dielectric 216B (i.e., the gate dielectric thickness) for the second driver MOSFET 216 is decreased to be smaller than that of each of the other MOSFETs 212, 214, 218, 220, and 222, in one embodiment of the present invention. Similarly as described above for the signal converter 122 of FIG. 2, the sensitivity of the signal converter 202 of FIG. 6, S_{V}, is expressed as follows:
S_{V}=CE×AVₜₒₜₐₗ

CE is the charge transfer efficiency, and AVₜₒₜₐₗ is the total voltage gain through the three source follower stages 206, 208, and 210. Thus, AVₜₒₜₐₗ is expressed as follows:
AVₜₒₜₐₗ=AV₁ₛₜ×AV_{2nd}×AV_{3rd}
AV₁ₛₜ is the voltage gain of the first source follower stage 206, AV_{2nd} is the voltage gain of the second source follower stage 208, and AV_{3rd} is the voltage gain of the third source follower stage 210.

The voltage gain AV for any source follower stage is expressed as follows:
AV=gₘ/(gₘ+g_{ds}+g_{mb})
gₘ is the transconductance, g_{ds} is the conductance through the channel, and g_{mb} is the back-gate transconductance, for the driver MOSFET of the source follower stage. The transconductance gₘ for a driver MOSFET is generally expressed as follows:
gₘ=[2μₒₓCₒₓ(W/L)I_{D}]^{1/2}
μₒₓ is the charge mobility, C_{OX} is the gate capacitance, W is the gate width, L is the gate length, and I_{D} is the drain current, for the driver MOSFET.

Furthermore, referring to FIGS. 6 and 19, the signal converter 202 is part of an output circuit 302 used within an imaging system 300. Referring to FIGS. 1 and 19, the array of photo-diodes 102 and the CCD's (charge coupled devices) 104, 106, 108, and 110 in FIG. 19 operate similarly as described above in reference to FIG. 1. In addition, the output MOSFET 114 and the reset MOSFET 118 in the output circuit 302 of FIG. 19 operates similarly as described above in reference to FIG. 1.

The charge transfer efficiency, CE, of the signal converter 202 is expresses as follows:
CE=q/C_{S}=q/[C_{FD}+C_{GS}+C_{GD}+C_{G}]
q is the electron charge, and referring to FIGS. 6 and 19, Cs is the total capacitance at the storage node 205 of the charge accumulation region 204. Similarly as described in reference to FIGS. 1 and 4, the total capacitance C_{S} for the storage node 205 of FIGS. 6 and 19 includes:
C_{FD} which is the capacitance of the floating diffusion junction 204;
C_{GS} which is the overlap capacitance between the gate and the source of the reset MOSFET 118;
C_{GD} which is the overlap capacitance between the gate and the drain of the output MOSFET 114; and
C_{G} which is the gate capacitance of the first driver MOSFET 212.

In the embodiment of FIG. 7, the thickness of the gate dielectric 216B for the second driver MOSFET 216 is decreased to increase the voltage gain AV_{2nd} of the second source follower stage 208. Thus, the total voltage gain AVₜₒₜₐₗ of the signal converter 202 is increased. However, decreasing the gate dielectric thickness for the second driver MOSFET 216 does not affect the charge transfer efficiency, CE, of the signal converter 202. As a result, the overall sensitivity, S_{V}=AVₜₒₜₐₗ×CE, of the signal converter 202 is increased from the prior art with the embodiment of FIG. 7.

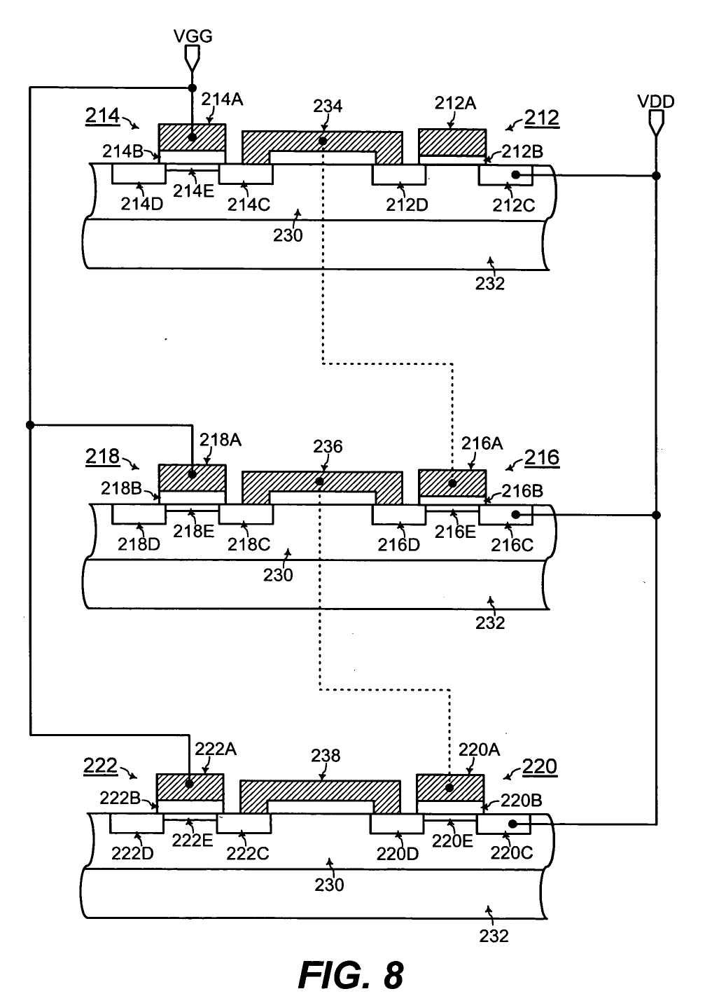

Referring to FIG. 8 for another embodiment of the present invention, the thickness of the gate dielectric 212B for the first driver MOSFET 212 is also decreased to be substantially same as the thickness of the gate dielectric 216B for the second driver MOSFET 216. Thus, the gate dielectric thicknesses for the first and second driver MOSFETs 212 and 216 are substantially same and are less than that of each of the other MOSFETs 214, 218, 220, and 222.

In that case, the voltage gains of the first and second stages 206 and 208, AV₁ₛₜ and AV_{2nd}, are each increased to in turn increase the total voltage gain AVₜₒₜₐₗ of the signal converter 202. With decrease of the thickness of the gate dielectric 212B for the first driver MOSFET 212, the charge transfer efficiency, CE, of the signal converter 202 is also decreased. However, the increase in the total voltage gain AVₜₒₜₐₗ may more than off-set such a decrease in charge transfer efficiency, CE, such that the overall sensitivity, S_{V}=AVₜₒₜₐₗ×CE, of the signal converter 202 is still increased from the prior art with the embodiment of FIG. 8.

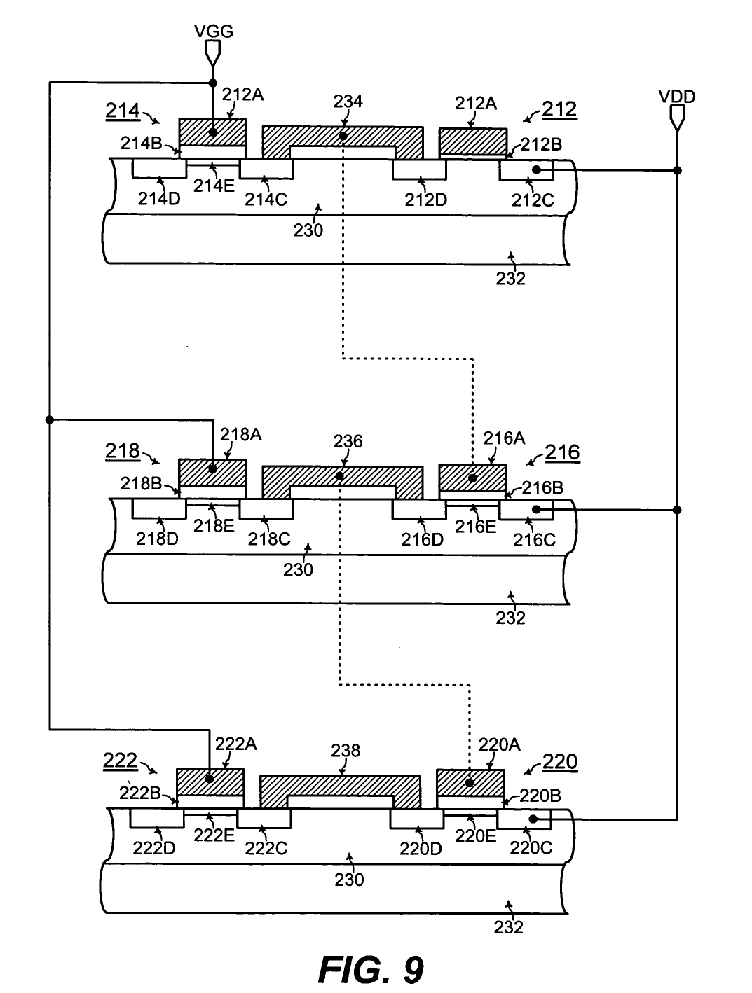

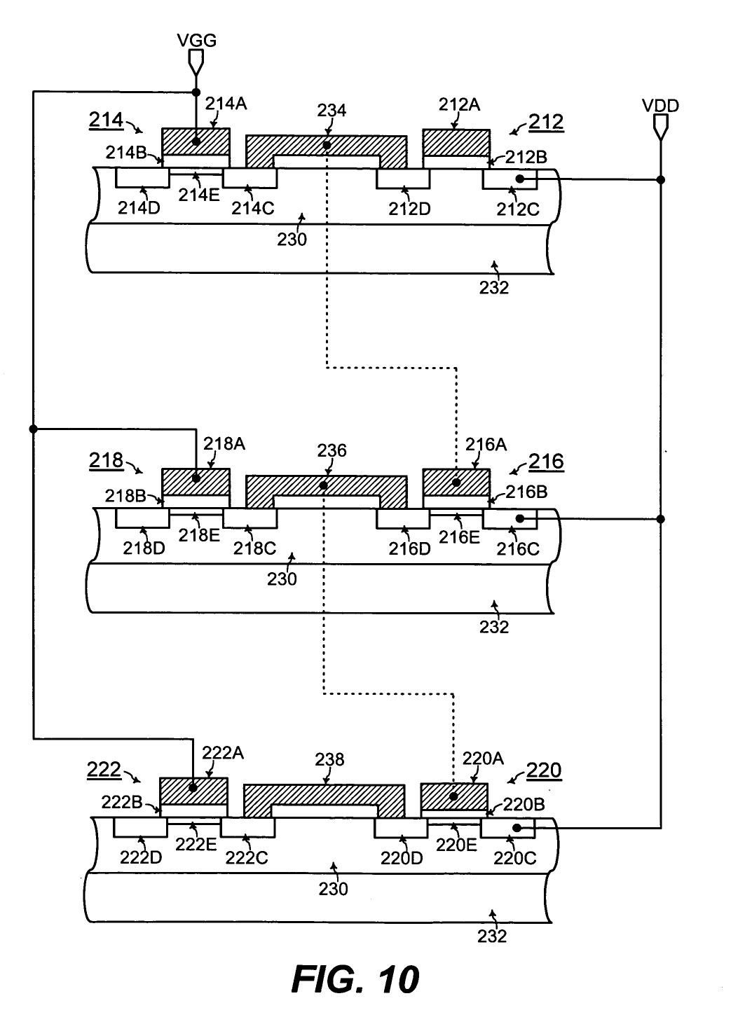

Referring to FIG. 9 for another embodiment of the present invention, the thickness of the gate dielectric 212B for the first driver MOSFET 212 is decreased even further to be less than the thickness of the gate dielectric 216B for the second driver MOSFET 216. Thus, the gate dielectric thicknesses for the first and second driver MOSFETs 212 and 216 are less than that of each of the other MOSFETs 214, 218, 220, and 222. In addition, the thickness of the gate dielectric 212B for the first driver MOSFET 212 is decreased even further from that of the second driver MOSFET 216.

In that case, the voltage gain of the first stage 206 in FIG. 9 is increased even further from the embodiment of FIG. 8. Thus, the total voltage gain AVₜₒₜₐₗ of the signal converter 202 of FIG. 9 is increased even further from the embodiment of FIG. 8. However, with the further decrease of the thickness of the gate dielectric 212B for the first driver MOSFET 212, the charge transfer efficiency, CE, of the signal converter 202 is also further decreased in FIG. 9 from the embodiment of FIG. 8. Nevertheless, the further increase in the total voltage gain AVₜₒₜₐₗ may more than off-set such a further decrease in charge transfer efficiency, CE, such that the overall sensitivity, S_{V}=AVₜₒₜₐₗ×CE, of the signal converter 202 is still increased from the prior art with the embodiment of FIG. 9.

Referring to FIG. 10 for another embodiment of the present invention, the thickness of the gate dielectric 220B (i.e., the gate dielectric thickness) for the third driver MOSFET 220 is decreased to be smaller than that of each of the other MOSFETs 212, 214, 216, 218, and 222. In that case, the voltage gain of the third stage 210 AV_{3rd} is increased to in turn increase the total voltage gain AVₜₒₜₐₗ of the signal converter 202.

However, decreasing the gate dielectric thickness for the third driver MOSFET 220 does not affect the charge transfer efficiency, CE, of the signal converter 202. As a result, the overall sensitivity, S_{V}=AVₜₒₜₐₗ×CE, of the signal converter 202 is increased from the prior art with the embodiment of FIG. 10.

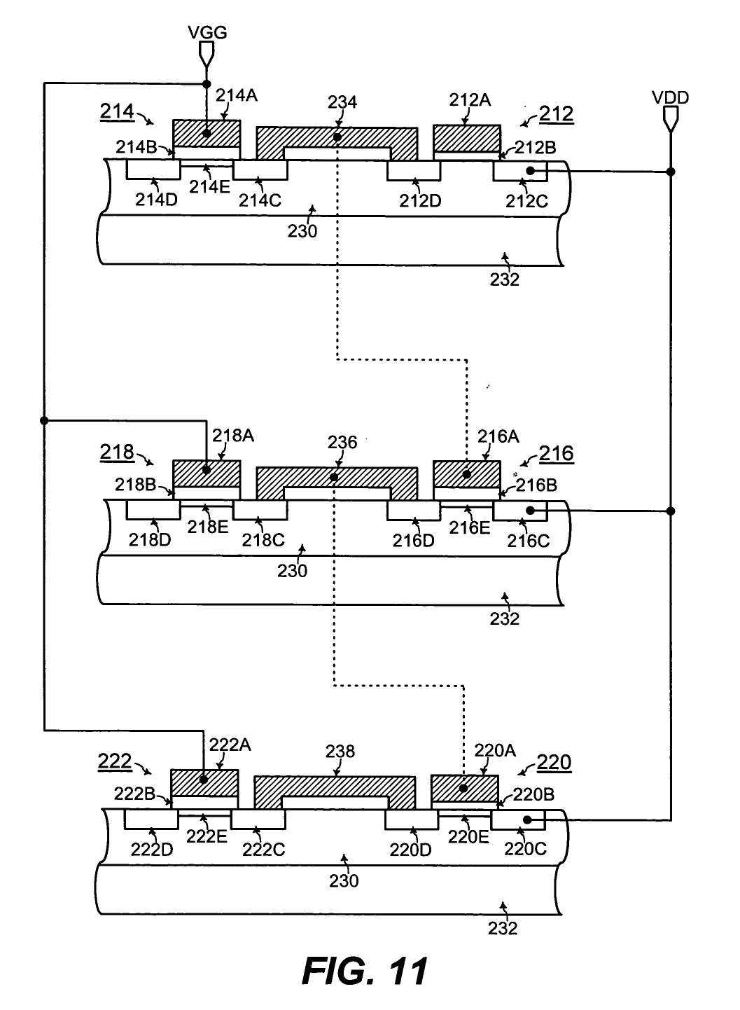

Referring to FIG. 11 for another embodiment of the present invention, the thickness of the gate dielectric 212B for the first driver MOSFET 212 is also decreased to be substantially same as the thickness of the gate dielectric 220B for the third driver MOSFET 220. Thus, the gate dielectric thicknesses for the first and third driver MOSFETs 212 and 220 are substantially same and are less than that of each of the other MOSFETs 214, 216, 218, and 222.

In that case, the voltage gains of the first and third stages 206 and 210, AV₁ₛₜ and AV_{3rd}, are each increased to in turn increase the total voltage gain AVₜₒₜₐₗ of the signal converter 202. With decrease of the thickness of the gate dielectric 212B for the first driver MOSFET 212, the charge transfer efficiency, CE, of the signal converter 202 is also decreased. However, the increase in the total voltage gain AVₜₒₜₐₗ may more than off-set such a decrease in charge transfer efficiency, CE, such that the overall sensitivity, S_{V}=AVₜₒₜₐₗ×CE, of the signal converter 202 is still increased from the prior art with the embodiment of FIG. 11.

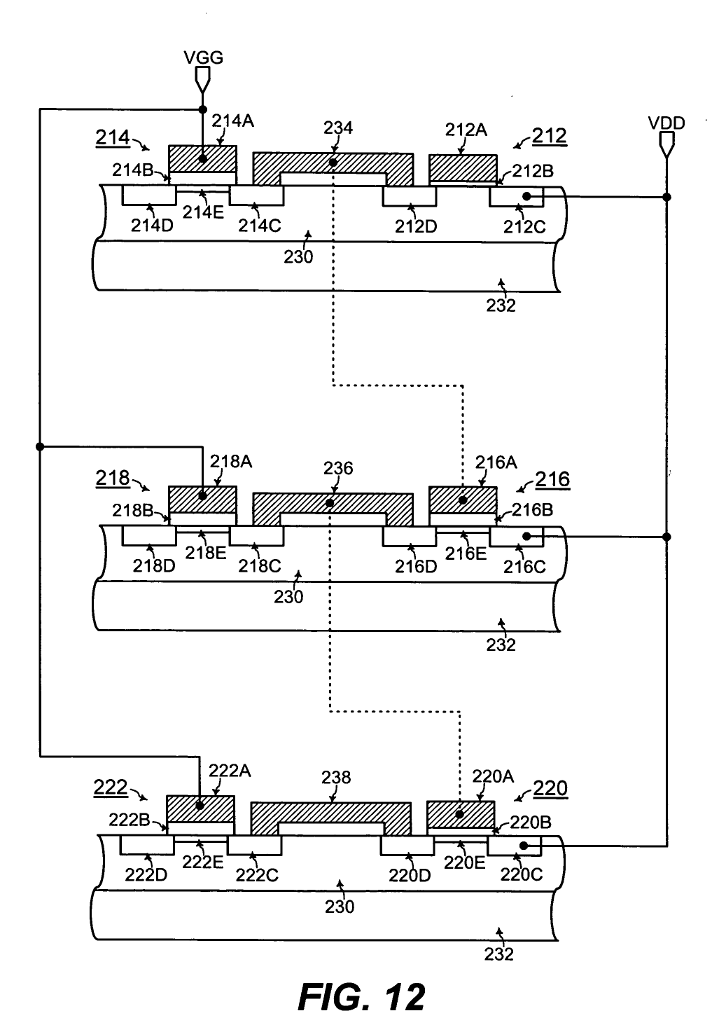

Referring to FIG. 12 for another embodiment of the present invention, the thickness of the gate dielectric 212B for the first driver MOSFET 212 is decreased even further to be less than the thickness of the gate dielectric 220B for the third driver MOSFET 220. Thus, the gate dielectric thicknesses for the first and third driver MOSFETs 212 and 220 are less than that of each of the other MOSFETs 214, 216, 218, and 222. In addition, the thickness of the gate dielectric 212B for the first driver MOSFET 212 is decreased even further from that of the third driver MOSFET 220.

In that case, the voltage gain of the first stage 206 in FIG. 12 is increased even further from the embodiment of FIG. 11. Thus, the total voltage gain AVₜₒₜₐₗ of the signal converter 202 of FIG. 12 is increased even further from the embodiment of FIG. 11. However, with the further decrease of the thickness of the gate dielectric 212B for the first driver MOSFET 212, the charge transfer efficiency, CE, of the signal converter 202 is also further decreased in FIG. 12 from the embodiment of FIG. 11. Nevertheless, the further increase in the total voltage gain AVₜₒₜₐₗ may more than off-set such a further decrease in charge transfer efficiency, CE, such that the overall sensitivity, S_{V}=AVₜₒₜₐₗ×CE, of the signal converter 202 is still increased from the prior art with the embodiment of FIG. 12.

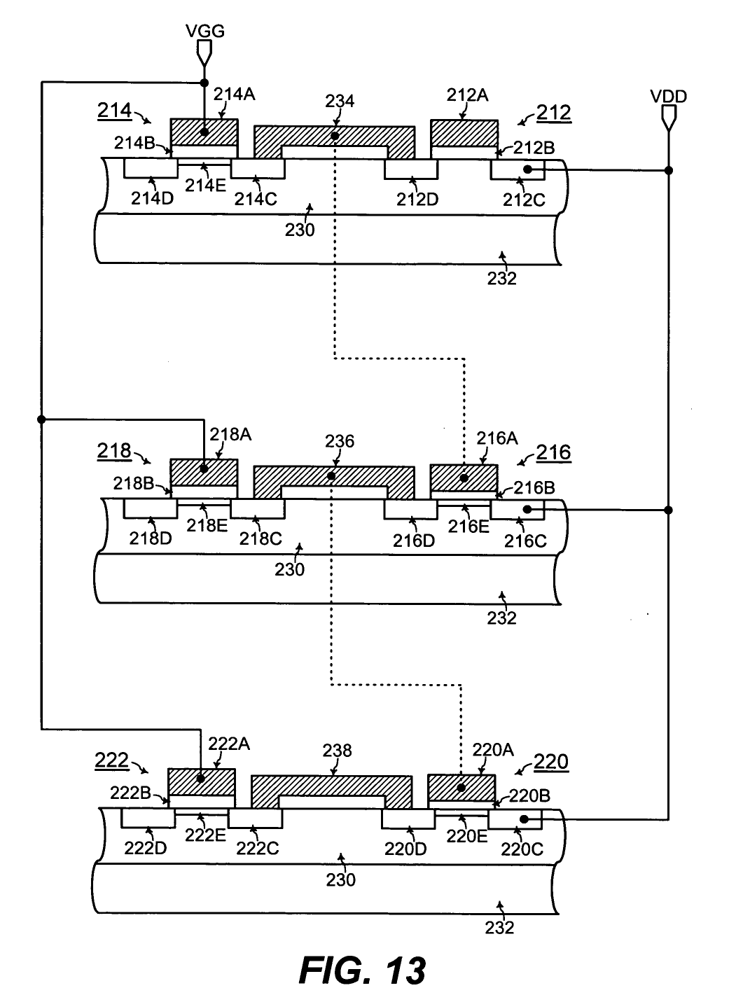

Referring to FIG. 13 for another embodiment of the present invention, the thickness of the gate dielectric 216B for the second driver MOSFET 216 and the thickness of the gate dielectric 220B for the third driver MOSFET 220 are substantially same and are decreased to be less than that of each of the other MOSFETs 212, 214, 218, and 222. In that case, the voltage gains of the second and third stages 208 and 210, AV_{2nd} and AV_{3rd}, are each increased to in turn increase the total voltage gain AVₜₒₜₐₗ of the signal converter 202.

However, decreasing the gate dielectric thicknesses for the second and third driver MOSFETs 216 and 220 does not affect the charge transfer efficiency, CE, of the signal converter 202. As a result, the overall sensitivity, S_{V}=AVₜₒₜₐₗ×CE, of the signal converter 202 is increased from the prior art with the embodiment of FIG. 13. In addition, decreasing the gate dielectric thicknesses for both of the second and third driver MOSFETs 216 and 220 in FIG. 12 increases the overall sensitivity of the signal converter 202 even further from the embodiments of FIG. 7 or 10 with decreased gate dielectric thickness for just one of the second or third driver MOSFETs 216 or 220.

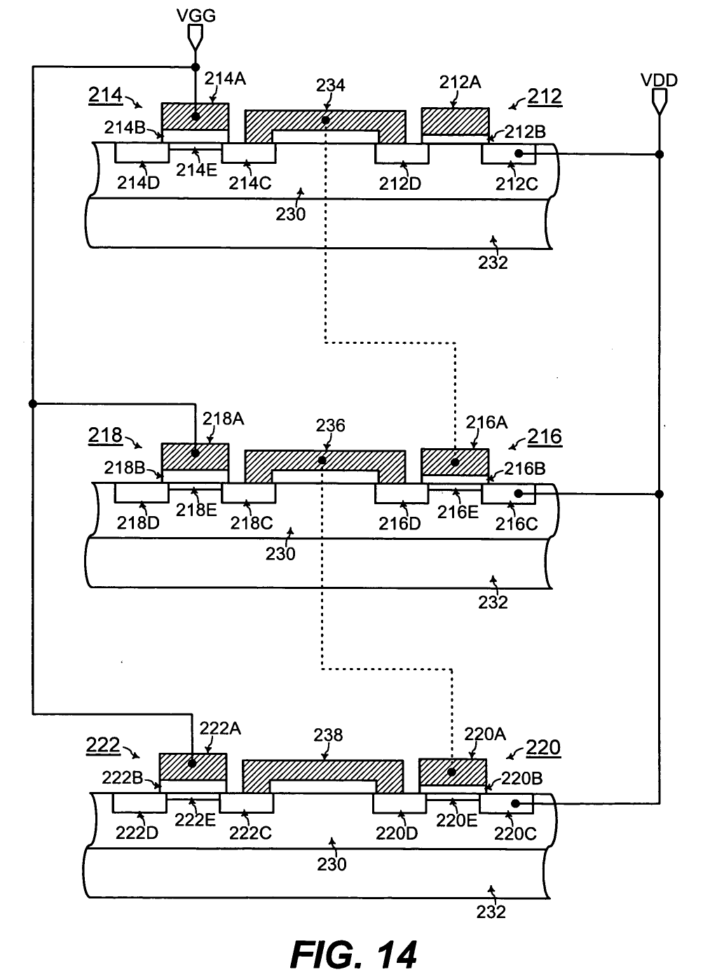

Referring to FIG. 14 for another embodiment of the present invention, the thicknesses of the gate dielectrics 212B, 216B, and 220B, for the first, second, and third driver MOSFETs 212, 216, and 220 are substantially same and are decreased to be less than that of each of the load MOSFETs 214, 218, and 222. In that case, the voltage gains of the first, second, and third stages 206, 208 and 210, AV₁ₛₜ, AV_{2nd}, and AV_{3rd}, are each increased to in turn increase the total voltage gain AVₜₒₜₐₗ of the signal converter 202.

With decrease of the thickness of the gate dielectric 212B for the first driver MOSFET 212 in FIG. 14, the charge transfer efficiency, CE, of the signal converter 202 is also decreased. However, the increase in the total voltage gain AVₜₒₜₐₗ may more than off-set such a decrease in charge transfer efficiency, CE, such that the overall sensitivity, S_{V}=AVₜₒₜₐₗ×CE, of the signal converter 202 is still increased from the prior art with the embodiment of FIG. 14.

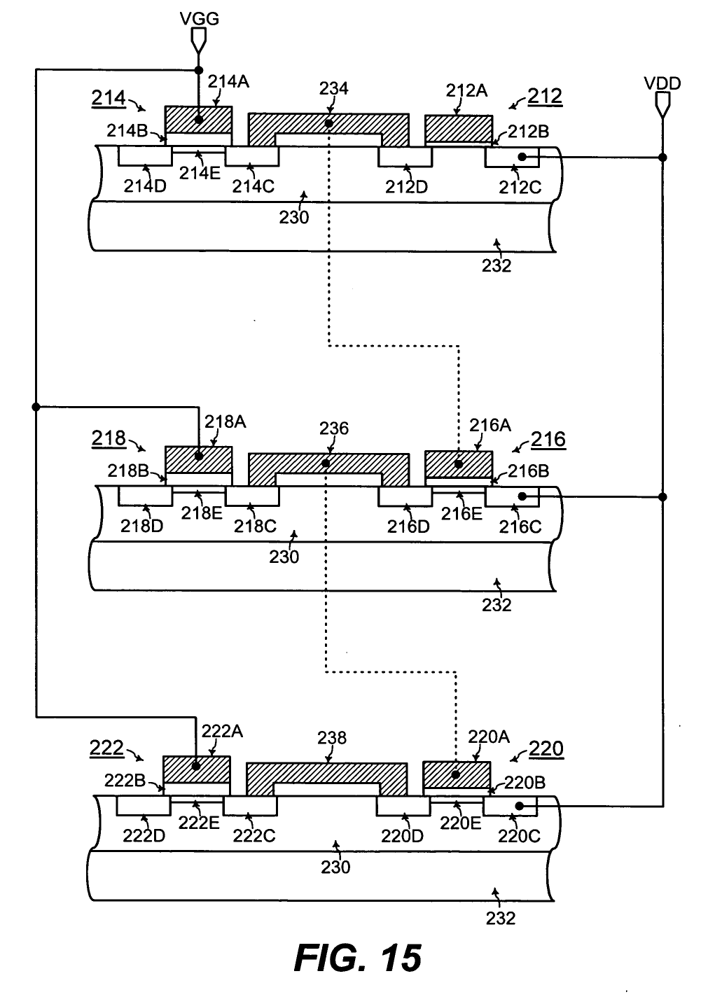

Referring to FIG. 15 for another embodiment of the present invention, the thickness of the gate dielectric 212B for the first driver MOSFET 212 is decreased even further from the embodiment of FIG. 14. Thus, the gate dielectric thickness of the first driver MOSFET 212 is less than the same gate dielectric thicknesses for the second and third driver MOSFETs 216 and 220. The gate dielectric thicknesses for the second and third driver MOSFETs 216 and 220 are still less than that of each of the load MOSFETs 214, 218, and 222 in FIG. 15. In addition, the thickness of the gate dielectric 212B for the first driver MOSFET 212 is decreased even further from that of the second and third driver MOSFETs 216 and 220.

In that case, the voltage gain of the first stage 206 in FIG. 15 is increased even further from the embodiment of FIG. 14. Thus, the total voltage gain AVₜₒₜₐₗ of the signal converter 202 of FIG. 15 is increased even further from the embodiment of FIG. 14. However, with the further decrease of the thickness of the gate dielectric 212B for the first driver MOSFET 212, the charge transfer efficiency, CE, of the signal converter 202 is also further decreased in FIG. 15 from the embodiment of FIG. 14. Nevertheless, the further increase in the total voltage gain AVₜₒₜₐₗ may more than off-set such a further decrease in charge transfer efficiency, CE, such that the overall sensitivity, S_{V}=AVₜₒₜₐₗ×CE, of the signal converter 202 is still increased from the prior art with the embodiment of FIG. 15.

In this manner, with the embodiments of the present invention as illustrated in FIGS. 7-15, the gate dielectric thickness is decreased for at least one subsequent driver MOSFET 216 and/or 220 disposed after the first driver MOSFET 212 in the signal converter 202. By decreasing such a gate dielectric thickness, the total voltage gain AVₜₒₜₐₗ is increased without affecting the charge transfer efficiency CE such that the overall sensitivity, S_{V}=AVₜₒₜₐₗ×CE, of the signal converter 202 is advantageously increased from the prior art. Thus, the gate dielectric thickness for at least one subsequent driver MOSFET 216 and/or 220 is preferably decreased as much as possible, limited by the break-down voltage of such a thin gate dielectric.

Furthermore, the present invention may be practiced with other gate dielectric thickness relationships from the example embodiments as illustrated in FIGS. 7-15. For example, the gate dielectric thickness for the third driver MOSFET 220 may be further decreased from that of the second driver MOSFET 216, and vice versa, with such gate dielectric thicknesses for the MOSFETs 216 and 220 also being less than the respective gate dielectric thickness for each of the other MOSFETs 212, 214, 218, and 222. Generally for the present invention, the gate dielectric thickness is decreased for at least one subsequent driver MOSFET 216 and/or 220 disposed after the first driver MOSFET 212.

In addition, in some of the embodiments of the present invention in FIGS. 7-15, the gate dielectric thickness is decreased for the first driver MOSFET 212 with a corresponding decrease in the charge transfer efficiency CE. However, because the gate dielectric thickness is also decreased for at least one subsequent driver MOSFET 216 and/or 220, the increase in the total voltage gain AVₜₒₜₐₗ may more than off-set such a decrease in charge transfer efficiency, CE, such that the overall sensitivity, S_{V}=AVₜₒₜₐₗ×CE, of the signal converter 202 is still increased from the prior art.

The foregoing is by way of example only and is not intended to be limiting. For example, any dimension, number, and material specified or illustrated herein is by way of example only. Additionally, it is to be understood that terms and phrases such as “after” and “subsequent” as used herein refer to relative location and orientation of various portions of the structures with respect to one another, and are not intended to suggest that any particular absolute orientation with respect to external objects is necessary or required.

For example, although three source follower stages 206, 208, and 210 are illustrated in FIGS. 6-15, the present invention may also be practiced with an intervening stage there-between. The present invention may generally be practiced when the gate dielectric thickness for at least one subsequent driver MOSFET that is disposed after the first source follower stage 206 is decreased for increasing the overall sensitivity of the signal converter.

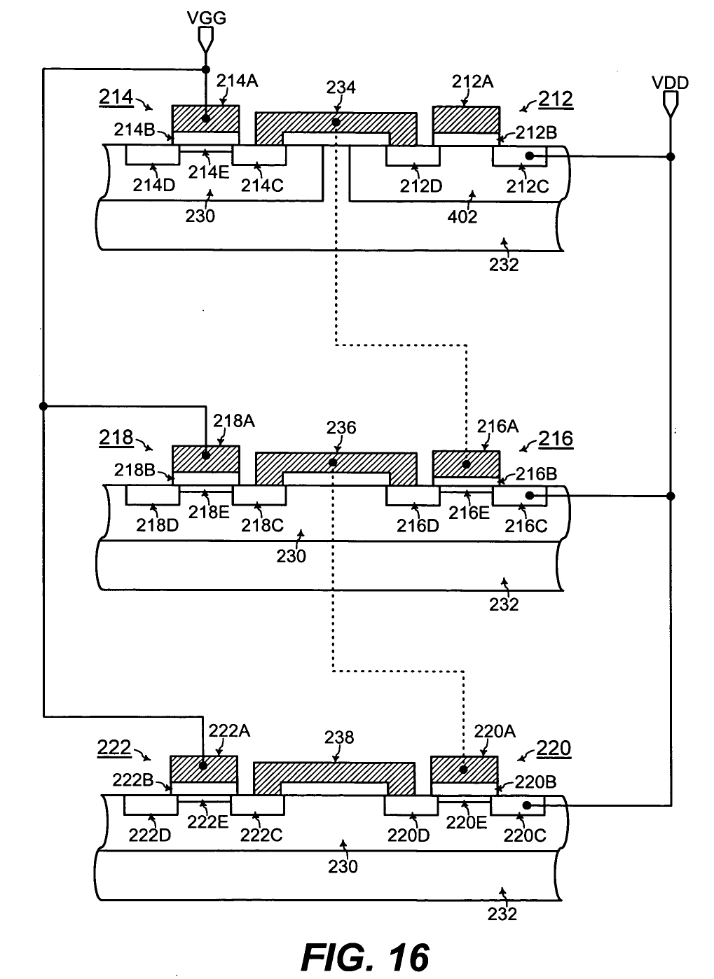

In addition, the signal converter with increased overall sensitivity according to the present invention may also be implemented in other ways from the embodiments as illustrated in FIGS. 6-15. For example, referring to FIG. 16 for another embodiment of the present invention, the first driver MOSFET 212 is formed within an isolated P-well 402 that is separate from the P-well 230 having the other MOSFETs 214, 216, 218, 220, and 222 formed therein.

In the embodiment of FIG. 16, the isolated P-well 402 results in less noise for the signal converter 202 since the first driver MOSFET 212 coupled to the charge accumulation region 204 is isolated from the other MOSFETs 214, 216, 218, 220, and 222. In addition, the dopant concentration of the isolated P-well 402 may be decreased to decrease the back-gate transconductance g_{mb} of the first driver MOSFET 212 thereby increasing the total voltage gain AVₜₒₜₐₗ of the signal converter 202. The embodiment of FIG. 16 is similar to the embodiment of FIG. 7, but with the isolated P-well 402 for the first driver MOSFET 212. In addition, the isolated P-well 402 for the first driver MOSFET 212 may also be formed for any of the other embodiments of FIGS. 8-15.

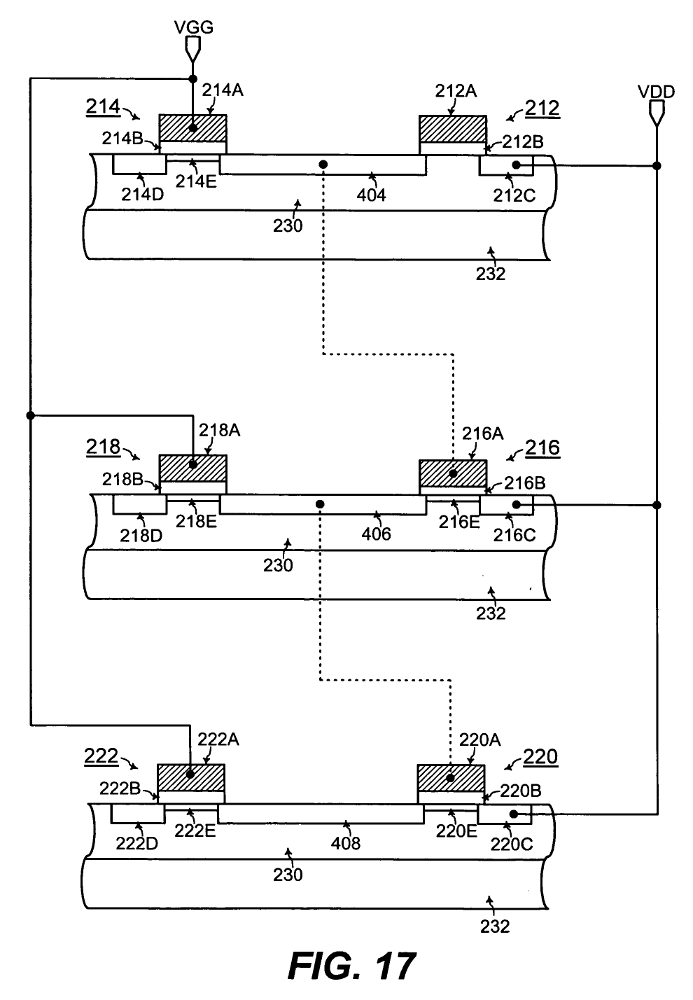

Referring to FIG. 17 for another embodiment of the present invention, the source of the driver MOSFET is merged with the drain of the load MOSFET for each of the source follower stages 206, 208, and 210. Thus, referring to FIGS. 7 and 17, the source 212D of the first driver MOSFET 212 and the drain 214C of the first load MOSFET 214 are merged together into one junction 404. Similarly, the source 216D of the second driver MOSFET 216 and the drain 218C of the second load MOSFET 218 are merged together into one junction 406. Additionally, the source 220D of the third driver MOSFET 220 and the drain 222C of the third load MOSFET 222 are merged together into one junction 406.

With such an embodiment of FIG. 17, the interconnect structures 234, 236, and 238 are advantageously not used for coupling the source of the driver MOSFET to the drain of the load MOSFET for each of the source follower stages 206, 208, and 210. In addition, the area occupied by the source of the driver MOSFET and the drain of the load MOSFET may advantageously be decreased with such merging in FIG. 17.

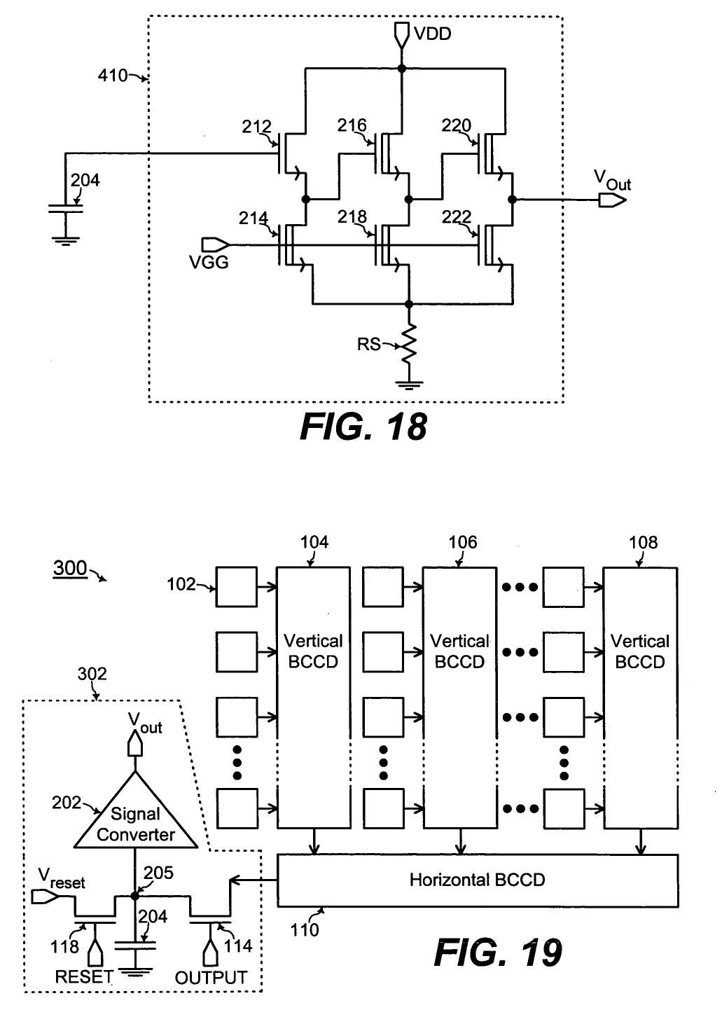

FIG. 18 shows a signal converter 410 according to another embodiment of the present invention. The signal converter 410 of FIG. 18 is similar to the signal converter 202 of FIG. 6. However in FIG. 18, the sources of the load MOSFETs 214, 218, and 222 are coupled together to ground via a same resistor RS. In contrast in FIG. 6, each source of the load MOSFETs 214, 218, and 222 is coupled to ground via a respective resistor R1, R2, and R3. In any case, a resistor at the source of a load MOSFET increases the effective load resistance at the drain of such a load MOSFET.

In the embodiment of FIG. 18, the resistance value of one resistor RS is easier to control for more consistent operation of each of the source follower stages. On the other hand, because of coupling of the source follower stages through the common resistor RS, the signal converter 410 of FIG. 18 is more prone to noise. Thus, the signal converter 202 of FIG. 6 may be preferred for operation in a noisy environment.

In any case, FIGS. 6-18 illustrate example embodiments of the present invention. The present invention may also be practiced with other embodiments not specifically illustrated and described herein. The present invention is limited only as defined in the following claims and equivalents thereof.

1. A signal converter for converting signal charge into a voltage, comprising:
a first driver FET that receives the signal charge; and
a subsequent driver FET that is coupled to an output of the first driver FET,
wherein a gate dielectric thickness of the subsequent driver FET is less than a gate dielectric thickness of at least one other FET of the signal converter.

2. The signal converter of claim 1, wherein the first driver FET is for a first stage, and wherein the subsequent driver FET is for a second stage after the first stage.

3. The signal converter of claim 2, wherein the gate dielectric thickness of the subsequent driver FET is less than a gate dielectric thickness of the first driver FET.

4. The signal converter of claim 2, wherein the gate dielectric thickness of the subsequent driver FET is substantially equal to a gate dielectric thickness of the first driver FET.

5. The signal converter of claim 2, wherein a gate dielectric thickness of the first driver FET is less than the gate dielectric thickness of the subsequent driver FET.

6. The signal converter of claim 1, wherein the first driver FET is for a first stage, and wherein the subsequent driver FET is for a third stage coupled to the first stage via a second stage having a second driver FET.

7. The signal converter of claim 6, wherein the gate dielectric thickness of the subsequent driver FET is less than a gate dielectric thickness of the first driver FET.

8. The signal converter of claim 6, wherein the gate dielectric thickness of the subsequent driver FET is substantially equal to a gate dielectric thickness of the first driver FET.

9. The signal converter of claim 6, wherein a gate dielectric thickness of the first driver FET is less than the gate dielectric thickness of the subsequent driver FET.

10. The signal converter of claim 6, wherein the gate dielectric thickness of the subsequent driver FET is less than a same gate dielectric thickness for the first and second driver FETs.

11. The signal converter of claim 1, further comprising:
a last driver FET coupled to an output of the subsequent driver FET to generate an output voltage.

12. The signal converter of claim 11, wherein the gate dielectric thickness of the subsequent driver FET is less than a gate dielectric thickness of the last driver FET.

13. The signal converter of claim 11, wherein the gate dielectric thickness of the subsequent driver FET is substantially equal to a gate dielectric thickness of the last driver FET.

14. The signal converter of claim 11, wherein a gate dielectric thickness of the last driver FET is less than the gate dielectric thickness of the subsequent driver FET.

15. The signal converter of claim 11, wherein the gate dielectric thickness of the subsequent driver FET is less than a same gate dielectric thickness for the first and last driver FETs.

16. The signal converter of claim 11, wherein each of the driver FETs is coupled to a respective load FET.

17. The signal converter of claim 16, wherein each of the driver FETs has a same gate dielectric thickness that is less than a gate dielectric thickness of at least one of the load FETs.

18. The signal converter of claim 1, wherein each of the driver FETs is coupled to a respective load FET.

19. The signal converter of claim 18, wherein the gate dielectric thickness of the subsequent driver FET is less than a gate dielectric thickness of at least one of the load FETs.

20. The signal converter of claim 18, wherein the gate dielectric thickness of the subsequent driver FET is less than each respective gate dielectric thickness for all of the load FETs.

21. The signal converter of claim 18, wherein each load FET is coupled to ground via a respective resistor.

22. The signal converter of claim 18, wherein each load FET is coupled together to ground via a same resistor.

23. The signal converter of claim 1, wherein the gate dielectric thickness of the subsequent driver FET is less than each respective gate dielectric thickness for all other FETs of the signal converter.

24. The signal converter of claim 1, wherein the first driver FET is an enhancement-mode MOSFET, and wherein all other FETs of the signal converter are depletion-mode MOSFETs.

25. The signal converter of claim 1, wherein the driver FETs are each configured as a source follower.

26. The signal converter of claim 1, wherein the first driver FET is formed within an isolated well.

27. The signal converter of claim 1, wherein the signal charge is output from a CCD (charge coupled device).

28. A signal converter for converting signal charge into a voltage, comprising:
a plurality of stages, each stage having a driver FET and a load FET with a foremost stage receiving the signal charge, and with each subsequent stage receiving a voltage from a prior stage; and
means for increasing voltage gain without decreasing charge transfer efficiency of the signal converter.

29. The signal converter of claim 28, wherein the driver FETs are each configured as a source follower.

30. The signal converter of claim 28, wherein a source of the load FET of each stage is coupled to ground via a respective resistor.

31. The signal converter of claim 28, wherein a source of the load FET of each stage is coupled to ground via a same resistor.

32. The signal converter of claim 28, wherein the driver FET of the foremost stage is formed within an isolated well.

33. The signal converter of claim 28,
wherein the driver FET of the foremost stage is sized to minimize gate capacitance;
and wherein the driver FET of a last stage is sized to supply sufficient current to drive a load coupled to an output of the last stage;
and wherein the driver FET of an intermediate stage is sized for current amplification between the driver FETs of the foremost and last stages.

34. An output circuit for a charge transfer element, comprising:
a region for accumulating charge from the charge transfer element to generate a signal charge;
a signal converter for converting the signal charge into a voltage, the signal converter including:
a first driver FET that receives the signal charge; and
a subsequent driver FET that is coupled to an output of the first driver FET,
wherein a gate dielectric thickness of the subsequent driver FET is less than
a gate dielectric thickness of at least one other FET of the signal converter;
a reset transistor that turns on to reset the region to a reset voltage; and
an output transistor that turns on to transfer the charge from the charge transfer element to the region.

35. The output circuit of claim 34, wherein the first driver FET is for a first stage, and wherein the subsequent driver FET is for a second stage after the first stage.

36. The output circuit of claim 34, wherein the first driver FET is for a first stage, and wherein the subsequent driver FET is for a third stage coupled to the first stage via a second stage.

37. The output circuit of claim 34, wherein the signal converter further comprises:
a last driver FET coupled to an output of the subsequent driver FET to generate an output voltage.

38. The output circuit of claim 37, wherein each of the driver FETs is coupled to a respective load FET.

39. The output circuit of claim 38, wherein each of the driver FETs has a same gate dielectric thickness that is less than a gate dielectric thickness of at least one of the load FETs.

40. The output circuit of claim 34, wherein the driver FETs are each configured as a source follower.

41. The output circuit of claim 34, wherein each of the driver FETs is coupled to a respective load FET.

42. The output circuit of claim 41, wherein the gate dielectric thickness of the subsequent driver FET is less than a gate dielectric thickness of at least one of the load FETs.

43. The output circuit of claim 41, wherein each load FET is coupled to ground via a respective resistor.

44. The output circuit of claim 41, wherein each load FET is coupled together to ground via a same resistor.

45. The output circuit of claim 34, wherein the first driver FET is an enhancement-mode MOSFET, and wherein all other FETs of the signal converter are depletion-mode MOSFETs.

46. The output circuit of claim 34, wherein the first driver FET is formed within an isolated well.

47. The output circuit of claim 34, wherein the charge transfer element is a CCD (charge coupled device).

48. An imaging system, comprising:
an array of photo-diodes, each photo-diode accumulating a respective signal charge;
at least one charge transfer element coupled to the array of photo-diodes for shifting the respective signal charge from each photo-diode; and
an output circuit coupled to the at least one charge transfer element, the output circuit comprising:
a region for accumulating the respective signal charge shifted from the charge transfer element; and
a signal converter for converting the respective signal charge accumulated at the region into a voltage, the signal converter comprising:
a first driver FET that receives the respective signal charge; and
a subsequent driver FET that is coupled to an output of the first driver FET,
wherein a gate dielectric thickness of the subsequent driver FET is less than a gate dielectric thickness of at least one other FET of the signal converter.

49. The imaging system of claim 48, wherein the first driver FET is for a first stage, and wherein the subsequent driver FET is for a second stage after the first stage.

50. The imaging system of claim 48, wherein the first driver FET is for a first stage, and wherein the subsequent driver FET is for a third stage coupled to the first stage via a second stage.

51. The imaging system of claim 48, wherein the signal converter further comprises:
a last driver FET coupled to an output of the subsequent driver FET to generate an output voltage.

52. The imaging system of claim 51, wherein each of the driver FETs is coupled to a respective load FET.

53. The imaging system of claim 52, wherein each of the driver FETs has a same gate dielectric thickness that is less than a gate dielectric thickness of at least one of the load FETs.

54. The imaging system of claim 48, wherein each of the driver FETs is coupled to a respective load FET.

55. The imaging system of claim 54, wherein the gate dielectric thickness of the subsequent driver FET is less than a gate dielectric thickness of at least one of the load FETs.

56. The imaging system of claim 54, wherein each load FET is coupled to ground via a respective resistor.

57. The imaging system of claim 54, wherein each load FET is coupled together to ground via a same resistor.

58. The imaging system of claim 48, wherein the driver FETs are each configured as a source follower.

59. The imaging system of claim 48, wherein the first driver FET is an enhancement-mode MOSFET, and wherein all other FETs of the signal converter are depletion-mode MOSFETs.

60. The imaging system of claim 48, wherein the first driver FET is formed within an isolated well.

61. The imaging system of claim 48, wherein the charge transfer element is a CCD (charge coupled device).

62. The imaging system of claim 48, wherein the output circuit further comprises:
a reset transistor that turns on to reset the region to a reset voltage; and
an output transistor that turns on to transfer the respective signal charge from the charge transfer element to the region,
wherein the reset transistor is turned off when the output transistor is turned on.
